(19) United States
(12) Patent Application Publication
(10) Pub. No.: US 2025/0250682 A1
(43) Pub. Date: Aug. 7, 2025

(54) Systems and Methods for Depositing Alternating Layers for a Diamond-Like Coating

(71) Applicant: Thin Film Service, Inc., Livermore, CA (US)

(72) Inventor: Ollivier Lefevre, Pleasanton, CA (US)

(21) Appl. No.: 18/665,999

(22) Filed: May 16, 2024

Related U.S. Application Data
(60) Provisional application No. 63/550,218, filed on Feb. 6, 2024.

(51) Int. Cl. C23C 28/00; C23C 14/14; C23C 14/50; C23C 16/26; C23C 16/458; C23C 16/505

(52) U.S. Cl. CPC C23C 28/343; C23C 14/14; C23C 14/505; C23C 16/26; C23C 16/4584; C23C 16/505; C23C 28/32

(57) ABSTRACT

A deposition system for forming coatings, can include: a deposition chamber; a substrate in the deposition chamber configured for receiving a vapor deposition; a motor operably coupled with the substrate to rotate the substrate; a first deposition source separated from the substrate; a second deposition source separated from the substrate, wherein the second deposition source is configured to generate a second deposition material that is different from a first deposition material generated by the first deposition source; a divider in the deposition chamber between the first deposition source and the second deposition source. At least one of the first deposition source or second deposition source includes an inductively coupled plasma generator. A method of forming a deposited material can include forming a hybrid material from the first deposition material and second deposition material while rotating the substrate, wherein the hybrid material includes alternating layers or blending.

### CROSS-REFERENCE TO RELATED APPLICATIONS

This patent application claims priority to U.S. Provisional Application No. 63/550,218 filed Feb. 6, 2024, which provisional is incorporated herein by specific reference in its entirety.

### BACKGROUND

### Field

The present disclosure relates to systems and methods for depositing alternating layers of a diamond-like coating (DLC) and diamond-like nanocomposites (DLN).

### Description of Related Art

Coating materials have been created to solve a variety of issues and satisfy a wide range of needs. Polymers are commonly used in coating materials due to the way they can be synthesized and applied for tailored applications. When a surface is exposed to various environments and used for certain endeavors, polymers can be developed to improve the functionality of the surface in view of the application and environment. However, polymers can be deficient in many applications due to breaking down under stress or force.

For high stress or force applications, it is generally known to coat substrates with thin films of diamond-like carbon (DLC) or diamond-like nanocomposite (DLN). The DLN films are amorphous hydrogenated carbon films (a-C:H) that display high hardness and high elasticity combined with good corrosion protection, chemical inertness, and a smooth surface. The DLN films add temperature resistance, which make these films feasible for industrial applications, such as temperature resistant, hard, wear resistant, self-lubricating, and corrosion resistant coatings. There is a high demand in the market for low friction, corrosion and wear resistant hard substrate coatings, which can retain the favorable properties of DLC or DLN, while being exposed to higher temperature environments, in particular temperatures above 500° C. Additionally, there is a need for having better non-sticking or release properties.

DLCs are a class of amorphous carbon material that exhibits some of the properties of diamond, such as hardness, chemical resistance, and low friction. DLC coatings, on the other hand, are thin layers of DLC material applied onto the surface of various substrates, such as metals, ceramics, or polymers, to enhance their properties. DLN coatings are similar to DLC coatings in that they are thin layers applied onto substrates to enhance their properties. However, DLN coatings differ in their composition and properties. While DLC coatings consist primarily of carbon atoms arranged in a diamond-like structure, DLN coatings incorporate additional elements, such as silicon, hydrogen, or metal nanoparticles, into the carbon matrix. This addition of elements can modify the properties of the coating, such as increasing hardness, reducing friction, or enhancing adhesion. DLN coatings often exhibit improved performance compared to DLC coatings in specific applications, such as in reducing friction and wear in high-performance machining or improving the biocompatibility of medical implants.

DLN coatings have been deposited over different substrates used for biomedical, optical and tribological applications by plasma-enhanced chemical vapor deposition (PECVD). Some DLNs have an interconnecting network of amorphous hydrogenated carbon and quartz-like oxygenated silicon. Typical DLN growth rate is about 1 μm/h, measured by stylus profilometer.

A popular application is the use of DLN and DLC coatings onto electrostatic chucks whether a high current ion or minimum contact area (MCA) PVD electrostatic chucks (ESC). The low wear rate and excellent coefficient of friction makes DLNs a good candidate as it reduces backside particulates being generated between the silicon wafer and the ESC during thermal cycling. Existing technologies rely on either a-C:H hydrogenated based DLCs doped with silicon and oxygen deposited by a parallel plate RF 13.56 Mhz, MF 50-460 khz or pulsed DC substrate bias application on a rotating substrate. This requires complex equipment and processing to electrically charge the ESC while rotating it.

### SUMMARY

In some embodiments, a deposition system is configured for forming coatings, such as those described herein. The deposition system can include a deposition chamber and a substrate in the deposition chamber that is configured for receiving a vapor deposition. A motor is operably coupled with the substrate in order to rotate the substrate about an axis, such as an axis perpendicular with the deposition chamber surface. A first deposition source is included that is separated from the substrate by a distance. A second deposition source is also separated from the substrate. The second deposition source is configured to generate a second deposition material that is different from a first deposition material generated by the first deposition source. A divider is positioned in the deposition chamber between the first deposition source and the second deposition source. In some aspects, at least one of the first deposition source or second deposition source includes an inductively coupled plasma (ICP) generator. The other deposition source can be a sputter or other type of emitter. Also, two ICP generators can be included, which have different precursor materials. In some aspects, the first deposition source and second deposition source are each positioned to create a deposition that is substantially normal to the substrate.

In some embodiments, the first deposition source is configured for physical vapor deposition (PVD). In some aspects, the PVD is operably coupled with a metal supply or ceramic supply.

In some embodiments, the second deposition source is configured for plasma-enhanced chemical vapor deposition (PECVD). In some aspects, the PECVD is operably coupled with a plurality of material supplies for forming diamond-like coatings (DLC) or diamond-like nanocomposites (DLN).

In some embodiments, the divider extends longitudinally at least 25% of a trajectory length from the first and second deposition sources to the substrate, which can also be at least 40%, at least 50%, at least 60%, at least 75%, at least 90%, at least 95%, or at least 99% of such trajectory length.

In some embodiments, the divider extends laterally between the first and second deposition sources by at least 25% of a lateral length of the deposition chamber, which can also be at least 40%, at least 50%, at least 60%, at least 75%, at least 90%, at least 95%, or at least 99% of such lateral length.

In some embodiments, the inductively coupled plasma generator is remote from the deposition chamber.

In some embodiments, the substrate is un-biased during operation for deposition of materials.

In some embodiments, the deposition system includes a remote power supply configured as a radio frequency inductively coupled plasma generator.

In some embodiments, the metal supply includes materials selected from titanium, aluminum, chromium, gold, nickel, silver, copper, zirconium, tantalum, molybdenum, alloys thereof, or combinations thereof.

In some embodiments, the ceramic supply includes materials selected from silicon nitride, silicon dioxide, aluminum oxide, titanium dioxide, zirconium dioxide, tantalum pentoxide, hafnium dioxide, silicon carbide, boron nitride, gallium nitride, constituent atoms thereof, or combinations thereof.

In some embodiments, the plurality of material supplies for forming the DLC or DLN includes materials selected from silicone, organosilicone, hexamethyldisiloxane, dimethyladamantane, oxygen, nitrogen, carbon, silicon, hydrocarbon, fluorine, hydrogen, fluorinated hydrocarbon, DLC dopant, DLN dopant, or combinations thereof. The DLC and/or DLN dopants are well known in the art and incorporated herein.

In some embodiments, the deposition system can further include at least a first emitter manifold associated with the first deposition source within a first region relative to the divider, and at least a second emitter manifold associated with the second deposition source within a second region relative to the divider. In some aspects, the deposition system can include a plurality of first emitter manifolds in the first region and a plurality of second emitter manifolds in the second region. Each manifold can have one or more source materials, which can be precursors or dopants, or other materials.

In some embodiments, the divider has a shape that at least partially blocks or at least partially exposes a center hole in the substrate.

In some embodiments, a method of forming a deposited material can be performed with the deposition system of one of the embodiments. The operation of the system can include rotating the substrate during deposition. The method can include generating a first deposition material from the first deposition source with a trajectory towards the rotating substrate. The method can include generating a second deposition material from the second deposition source with a trajectory towards the rotating substrate. A hybrid material is formed from the first deposition material and second deposition material, wherein the hybrid material includes alternating layers or blending. That is, the layers can be distinct layers, which can be identified separately by known techniques. On the other hand, the blending can occur due to impact of atoms into the formed material that penetrate the material to distribute within the material instead of just at the surface. Such penetration of deposited materials can be used to blend the layers together or have gradients between the layers.

In some embodiments, the methods of operation can include at least one of: operating a power supply for the inductively coupled plasma generator with an energy range of 10 eV to 250 cV; depositing the hybrid material a rate of about 2.5 nm per second to about 9 μm per hour; rotating the substrate at about 200 to about 250 rotations per minutes via the motor; or creating a vacuum in the deposition chamber from about 1×10⁻⁷ mbar to about 5×10⁻⁶ mbar.

In some embodiments, the method can include forming a Sp2 rich film and transitioning to forming a Sp3 rich film; or forming a Sp3 rich film and transitioning to forming a Sp2 rich film. In some aspects, the transitioning includes modulating hydrogen content in the deposition chamber, which modulates the hydrogen content in a deposition layer of the hybrid material.

In some embodiments, the first deposition source and second deposition source are each positioned to create a deposition that is substantially normal to the substrate. In some aspects, the method can include creating a flux of the first deposition material toward the substrate in a first region of the deposition chamber and creating a flux of the second deposition material toward the substrate in a second region of the deposition chamber.

In some embodiments, the method can include generating a inductively coupled plasma with an RF plasma generator. In some aspects, the RF plasma generator is remote from the deposition chamber.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and following information as well as other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 includes a schematic diagram that shows a deposition chamber with a PVD source to the left and an ICP source to the right.

FIG. 2 shows the flux of DLC via the ICP source with a multitude of candidate dopants.

FIG. 3 includes a schematic diagram that shows both sides of the deposition chamber and the coating zones therein.

FIG. 4 illustrates a variety of different embodiments of a divider for the deposition chamber to separate the left chamber from the right chamber, which can separate a PVD from a PECVD.

FIG. 5 includes a schematic diagram that shows how one revolution and a pass through both chambers constructs the hybrid material, which can be separate layers or blended layers.

FIG. 6 includes a schematic diagram that shows a computing system that can be used as a controller, data receiver, data analyzer, or other computing task in accordance with the invention.

The elements and components in the figures can be arranged in accordance with at least one of the embodiments described herein, and which arrangement may be modified in accordance with the disclosure provided herein by one of ordinary skill in the art.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

Generally, the present technology relates to material deposition systems and processes having two emitters to deposit two different types of materials onto a rotating substrate. For example, the two emitters can emit materials to form various types of DLC or DLN materials that are harder, more wear resistant, and have better adhesion in a protocol that is much faster for depositing the materials. The two emitters are separated from each other by a dividing barrier so that they emit in separate regions of a deposition chamber. The substrate is configured with a motor to rotate the substrate so that a particular spot on the substrate rotates from one deposition region to the other deposition region. The systems and processes can be configured so that the deposition can be performed without a biasing connection to the substrate. The systems and methods allow for the formation of various alternating layered materials, which can stay as alternating layers or form into gradient layers with mixed properties. In some examples, the materials that are formed can include tetrahedral amorphous metal-doped DLCs, such as (t)a-C:H:(O), (t)a-C:H:(Si), or (t)a-C:H:(Me), which are possible with very high deposition rates. The improved system and processes described herein can be beneficial for reducing operation costs and providing a more reliable system with longer service life.

In some embodiments, one emitter can be a PVD emitter, and the other emitter can be a PECVD emitter (e.g., ICP). PECVD stands for Plasma-Enhanced Chemical Vapor Deposition, which is a process used to deposit thin films onto substrates using plasma-generated chemical reactions. In PECVD, a vacuum chamber is filled with a precursor gas or mixture of gases, typically organic or inorganic compounds. An electric field is then applied to the chamber to create a plasma, which is a highly energetic state of matter containing ions, electrons, and excited species. The plasma enhances the chemical reactions between the precursor gases, causing them to break down and deposit as a thin film onto the substrate. PECVD offers several advantages over other deposition techniques. It allows for lower deposition temperatures, which can be beneficial for depositing films onto temperature-sensitive substrates. It also enables precise control over film composition, thickness, and properties. Additionally, PECVD can be used to deposit a wide range of materials, including silicon dioxide (SiO₂), silicon nitride (Si₃N₄), amorphous silicon (a-Si), carbon-based films (such as DLC), and various other compounds. PECVD is widely used in industries such as microelectronics, photovoltaics, optics, and thin-film coatings for applications including semiconductor device fabrication, solar cell manufacturing, anti-reflective coatings, and barrier layers.

In PVD, thin films are deposited by the physical processes of evaporation or sputtering. Evaporation involves heating a solid material in a vacuum to produce vapor atoms, which then condense onto a substrate to form a thin film. Sputtering involves bombarding a target material with high-energy ions to eject atoms from the target, which then deposit onto a substrate. PVD relies on physical processes such as evaporation or sputtering to deposit material onto a substrate. The atoms or molecules of the material are physically transported from a source to the substrate without undergoing significant chemical changes. PVD is commonly used for depositing metallic films, such as aluminum, copper, titanium, and their alloys, as well as certain ceramic materials. In PECVD, thin films are deposited using plasma-enhanced chemical reactions. Precursor gases are introduced into a vacuum chamber, where they undergo chemical reactions in a plasma environment created by applying an electric field. The resulting reactive species form a thin film on the substrate through chemical reactions. PECVD involves chemical reactions between precursor gases in a plasma environment. The precursor gases undergo dissociation, ionization, and recombination to form thin films on the substrate. The plasma enhances the chemical reactions, leading to controlled deposition of the desired material. PECVD is often used for depositing thin films of insulating materials (e.g., silicon dioxide, silicon nitride), semiconductors (e.g., amorphous silicon), organic materials, and various compound materials with tailored properties.

The present technology relates to systems and methods to improve DLN and DLC coating properties when used in combination with ESC chucks. While the existing methods suffer from a low deposition rate and poor adhesion at higher temperatures, the present technology has high deposition rate and high adhesion at higher temperatures.

In some embodiments, the present systems and methods do not require the substrate to be biased. The system can operate when the substrate is not biased; however, applying some amount of bias to the substrate can also be performed. Instead, the deposition system can include an RF-ICP remote power supply, as further described herein. This power supply can be used for implementing the deposition processes.

In some embodiments, the systems and methods can be configured to deposit alternating monolayers of metal or ceramic and DLC or DLN materials. For example, the alternating layers can be between the dopant metal, metal oxides, and nitrides, as well as any layer of a DLC or DLN. Since the deposited layers are monolayers, the stack from alternating layers resembles a structure as if the coating was doped.

In some embodiments, the system and method allow transitioning between Sp2 rich films and Sp3 rich films, which can have tunable hydrogen content. Such a system and method are beneficial to create a coating that survives both the higher operating temperatures trending in the field (e.g., 100-300° C. for Sp2 or 300-600° C. for Sp3), while maintaining excellent adhesion to the substrate or its intermediate or base layer. The system and method allow for any blend between hydrocarbons and PVD materials along with the traditional dopants in DLC or DLN, such as oxygen, hydrogen, halides, and silicon. For example, freon is a dopant that can form a film that is superhydrophobic.

In some embodiments, the substrate bias power supply is omitted. Instead, the system includes an RF-ICP remote power supply, which is configured to produce high ion current density, high ion energy, and high deposition rates. The RF-ICP remote power supply can be connected to one deposition source or both deposition sources (when both plasma), or a separate RF-ICP remote power supply for each source. The PVD sputter may be operated with standard operating techniques. The RF-ICP stands for radio frequency inductively coupled plasma, which is a type of plasma that is generated using radio frequency (RF) energy to create a high-energy ionized gas. This type of plasma is often used in various industrial and scientific applications, including plasma processing, thin film deposition, surface modification, and analytical chemistry. A remote power supply in the context of RF-ICP refers to the RF generator or RF power supply unit that provides the RF energy needed to generate and sustain the plasma. This power supply unit is often located separately from the plasma chamber or reactor where the plasma is generated. An RF-ICP remote power supply can be a power supply unit that generates radio frequency energy to sustain a radio frequency inductively coupled plasma, and it is located separately from the plasma chamber or reactor.

The ion current density and ion energy can be controlled independently, thus deposition rate and packing force or stress can be controlled independently from one another while keeping the pressure fixed. The system can use any RF-ICP source with an energy range of 10 eV to 250 eV, which can be used to dry etch the substrate or can be used in deposition mode for DLC or DLN deposition.

The alternating layers can be performed with a deposition system having a deposition chamber with a side-by-side emitter system, which can include a PVD sputter arrangement and a PECVD plasma generator (e.g., plasma emitter) arrangement. That is, there are two deposition sources in the chamber, which are next to each other, with the divider therebetween. The distance between the two deposition sources can be varied along with travel distance to maximize the ability to do alternating layers. In some aspects, multiple layered materials can be formed from a deposition chamber having 2, 3, 4, 5, 6 or more separate emitters, which can be adjacent in a line, staggered, aligned, or in an array. At least one deposition source can be a sputter emitter, which can be configured generally as known in the art.

In some embodiments, the multi-emitter setup allows the deposition system to deposit single atomic monolayers to a few atomic monolayers from each deposition source individually while keeping the blended properties from the mixture of both fluxes. In order to perform such an alternating deposition, the electrical characteristics for the substrate can be properly configured. The system can secure the substrate or wafer to receive the alternating layers of deposition to the pedestal is for all types of clamping technologies, whether Johnsen Rahbek or Coulomb.

In some embodiments, a divider can be installed in the deposition chamber between the deposition sources. That is, each deposition source can be separated from each other by having a divider therebetween. The divider can be a planar member that is positioned between the deposition sources and extend a predetermined length towards the pedestal. Due to positioning of the divider, both sides of the reactor chamber (deposition chamber) remain clean and free from contamination. For example, neighboring contamination of the other emitter material can be avoided with the divider acting as a particle shield separating the emitters into their own compartments. Both sides can be separated by the divider that simultaneously functions as a deposition shield as the central divider. The divider can be sculpted or otherwise shaped to either fully block or fully expose the center hole or feed in the ESC chuck. This allows for a full metal deposition or full DLC or DLN deposition or a range of two or more deposition species.

Deposition of metal, metal organic liquids, silicon, oxygen, or combination thereof allows the formation of complex materials, such as amorphous ((t)a-C:H:Si:O:(Me)). Accordingly, DLC or DLN deposition is possible by a remote RF ICP plasma. The PECVD emitter can emit the remotely generated plasma or the material into the system to generate the plasma. The plasma generator, which can be remote from the deposition chamber or within the deposition chamber, can be any type. Examples of plasma generators include RF plasma generators, microwave plasma generators, electrodeless discharge lamps. In some aspects, the plasma is generated with a remotely generated RF-ICP system.

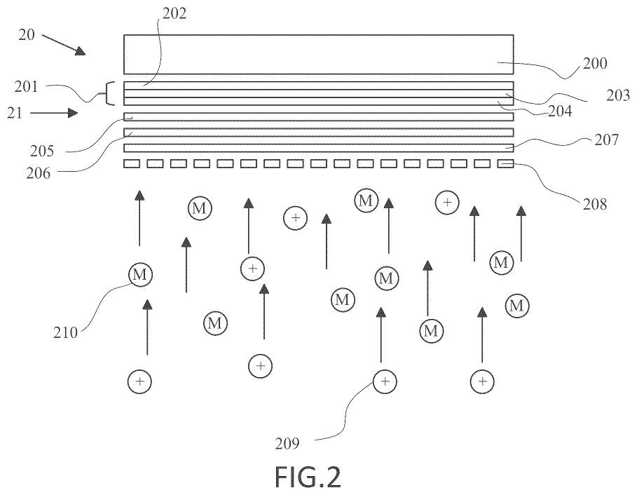

Additionally, hydrocarbon gasses and assist gases can be fed through the ICP source or entered into the chamber via trim gas manifolds situated between the source and the substrate. Furthermore, both PECVD DLC and metal/ceramic PVD sputter sources do not need to be angled for the co-deposition for this to be possible. The two deposition sources can be arranged to emit in parallel directions. The two deposition sources can have a parallel trajectory to the receiving surface that has an incidence angle that is normal (90 degrees), which normal incidence angle allows the use of deposition masks (e.g., mask 208 in FIG. 2) covering the substrate to be created without shadowing effects. This configuration improves the coating uniformity.

In some embodiments, the present system and method also allows for the ESC to have its front face in a vacuum in the deposition chamber, whilst the utilities or back of the assembly are positioned to be outside of the deposition chamber in the atmosphere, which reduces the risk of undetectable vacuum leaks and contamination. The mounting setup of the ESC can be identical to the setup used in production, thereby eliminating risks associated with the use outside the scope design of the ESC. The extra benefit is that the setup of the ESC can be leak checked while in process, which reduces the risk of failure.

In some embodiments, cold water (e.g., cooling) or hot water (e.g., heating) can be applied to the ESC, which can bring the surface of the ESC in the correct operational temperature window before any coating is applied. Temperature matching the ESC prior to deposition of any DLC or DLN layer can be beneficial for reducing the coating stress and improving adhesion. Substrate bias via the outside environment (e.g., outside the chamber) of the ESC is optional and could be beneficial when operating at higher pressure.

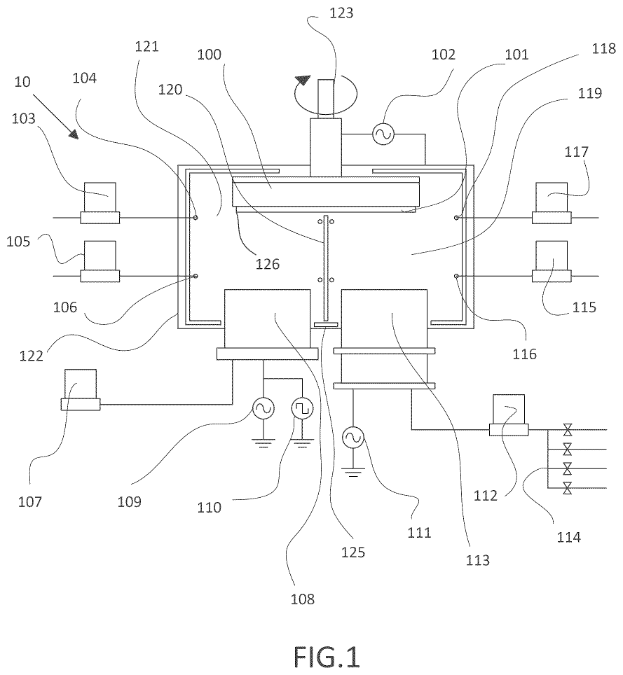

FIG. 1 illustrates an embodiment of a dual deposition source chamber 10 that can be used in a process for deposition of alternating layers of materials and shows chamber with a PVD source 108 to the left and an ICP source 113 to the right. FIG. 2 illustrates the deposition protocol 20 of the alternating layers of materials, with the flux of DLC via ICP with a multitude of candidate dopants. Accordingly, a deposition protocol 20 can be described in connection with the dual emitter deposition chamber 10 by reference to FIGS. 1 and 2 as follows.

Two monolayers that are formed from two different materials when deposited rapidly onto one another in alternating layers act not like two individual layers but act as though the two layers were blended or co-deposited, especially when there is ample energy applied. The deposition of such alternating layers can be applied on a deposition substrate 100, such as semiconductor pedestals or electrostatic chucks or ESC's. In some aspects, the ESC used in PVD processes can be known as the minimum contact area ESC (e.g., PVD MCA ESCs). However, such an embodiment is an example, and the present technology can be applied to high ion current ESCs where DLC and DLN coatings are also frequently used. In some aspects, the PVD MCA ESC uses a mask (e.g., mask 208 of FIG. 2), where the high ion current ESC usually does not use a mask. However, any type of ESC or other pedestal can be used with a mask 208.

A typical coating 21 (FIG. 2) of DLN or DLC can include a metallic interface layer 202, which can promote adhesion along with other characteristics like stress mitigation and promote electrical conductivity of the entire deposited layer. The metallic interface layer 202 can be titanium or a titanium nitride; however, any transition metal of 1b-7b, 8b groups (e.g., IB, IIB, IIIB, IVB, VB, VIB, VIIB, and VIIIB) of the periodic table can be used. Some applications can include an oxide layer 203 or nitride layer 204 or a blend of both. The interface layer 202 can be identified, and then an amorphous hydrogenated a-C:H DLC layer 205 can be formed. The a-C:H DLC layer 205 can be formed along with dopants, usually but not limited to Si and O. The dopants will be deposited onto the a-C:H DLC layer 205 so as to form a doped layer 206. There are several varieties of doped layer 206, where metal deposition continues while the doped DLC or DLN is being grown. The metal can be deposited as needed as the metal inside the DLC is useful to its application. However, it should be recognized that various separate layer and/or blended layer products can be obtained.

In some embodiments, the precursors used to form the layers can be custom compounds, such as organosilicon, or others known or recited herein. Often, the precursors can be liquids that are heated, evaporated, and introduced into the dual deposition source chamber 10 via a gas manifold 114 and from the ICP source 113 into the plasma in the chamber 122. The compounds in the precursors get dissociated and ions are created via the ICP source 113. The precursor hydrocarbons 209 accelerate towards the substrate 100 and impact with enough force to create DLC forming the layers (e.g., DLC layer 201, including layers 202, 203, and 204, as well as layer 205 and 206).

In some aspects, the configuration of the deposition system allows for the freedom to introduce these precursors into the ICP chamber 119 through a first gas manifold 116 (e.g., each gas manifold having an outlet for ejection) between the ICP source 113 and the substrate 100. The first gas manifold 116 can have modulated particle ejection that is controlled via a mass flow controller 115. Simultaneously, the precursors from gas manifold 114 can also be used as the feed gas to the source 113 through a mass flow controller 112, as almost any gas can be used via the manifold 114. Examples of such gases include argon, hydrogen, nitrogen, oxygen, and also hydrocarbons and/or organosilicons can be applied to the source 113 from the manifold 114 to be ionized before they enter the vacuum chamber 122.

Additionally, a second chamber manifold 118 can be used as a trim gas source through controlling a flow of species in the vicinity of the substrate 100 via a controlled mass flow controller 117. This allows trimming the DLC or DLN or its organosilicons to promote uniformity or the second chamber manifold 118 also allows adding inert gasses, other dopant gasses, such as oxygen, hydrogen, or any other precursor. The configuration with the first chamber manifold 116 and second chamber manifold 118 allows for the processing to tailor the emission to tailor the properties of the deposited material Additionally, the final layer does not need to be dictated by the precursor applied to the source.

Also, the PVD chamber 121 includes a corresponding first gas manifold 106 controlled by a first mass flow controller 105, and a closer second chamber manifold 104 controlled by a second mass flow controller 103. In the PVD chamber 121, the material being deposited as a metal or ceramic can be performed using a sputter magnetron source 108, which can be oxidized or nitrided in the PECVD ICP 101 section where the DLC or DLN is typically deposited. A stoichiometric compound is still achieved, and the deposition rate remains high. There is also no risk some of the edge areas near the PVD racetrack will be poisoned. The area around the sputter magnetron also remains clear from DLC or DLN deposits. The passage in the PECVD ICP section (ICP chamber 119) also allows the PVD film to be compacted, densified to promote adhesion which can be beneficial for this application.

In some embodiments, the film design relies on a fast-moving substrate, which rotates at typically 200-250 rpm via a motor 123. However, the rotation can be slower or faster depending on whether the speed of the incoming flux varies. The system is configured to time the duration it takes from the coating flux to travel through the mask 208, which is typically 5 mm but can be between 0.5 mm and 9 mm thick, and still reach the substrate 100/200, behind the mask 208 so the patterns can be formed. The sputter flux at 2-3 cV travels at around 1000 m/second, which allows for rotation to match the dwell time and create layers of about ˜0.5-1 nm in thickness.

A thin layer of titanium or one of the metals of the group can be deposited and can either be nitrided, oxidized or remain virgin as it passes the ICP source 113 through the ICP chamber 119 during rotation. The step will then repeat until the desired thickness is achieved, which is typically between 100 nm and 500 nm. In other embodiments, the layer can be as small as 5 nm and up to 1 micron as well.

The protocol can be varied depending on the product. In some aspects, the protocol has a decision of whether to keep either the metallic deposition on or off while activating the DLC or DLN deposition step. This decision depends on the application, and whether the ESC that is deposited onto is either the Johnson Rahbek type or coulomb type of electrostatic chuck. Their electrostatic release behavior requires either a capacitive non-conductive DLC or an electrically conductive DLC film. The metallic portion that is deposited into the DLC or DLN film will tailor to that characteristic.

Then, the protocol continues to alternate layers of PVD layer (e.g., PVD source 108) with DLC or DLN layer (e.g., ICP source 113) until achieving the desired thickness, which is typically 3-4 μm for one application and ranges between 20 nm and 1 μm for other applications. The protocol can be used to grow one or more layers to be as thick as 12 μm or thicker.

At the interface between the metallic layer and the start of the DLC or DLN layer, the process can tune the stress levels, so they compensate each other out or at least be close matching. This is within the system capabilities since the deposition chamber 122 can be configured to have a range from 0.1 GpA to over 35 GpA, and include the ability to hydrogenate, dope with hydrogen, or form a high Sp3 layer. At each point in the growing film, the processing can alter between a tetrahedral amorphous a-CH DLC or amorphous a-C:H DLC, or add Si:O:N:Me.

Also as shown, the substrate can be biased with the biasing component 102 to provide the current (e.g., current generator). The ICP source 113 can be biased with a biasing component 111 to provide the proper electrical current for operation. The PVD source 108 can also be biased with a biasing component 109 to provide proper electrical current, and where a wave form generator 110 can be used to provide operational waveforms for controlling the ejection of material from the PVD source 108. The PVD source 108 is coupled with a mass controller 107 that controls the input of material to be ejected from the PVD source 108. Notably, the biasing component 111 can be configured as the RF-ICP remote power source.

Notably, the ICP chamber 119 is separated from the PVD chamber 121 by the dividing wall 120. The dividing wall 120 is shown to extend from the emission wall 125 towards the substrate 100. As shown, the dividing wall 120 is shown to extend all the way to be adjacent to the substrate 100 and allow rotation and deposition, as well as application of the mask 208. However, the length from the emission wall 125 can be varied as needed or desired.

The deposited material of FIG. 2 also shows the substrate 200 having the alternating layers thereon with a top cap 207 thereon. The top cap 207 can be a passivated, treated with fluorine, or other material to protect the deposited layers. The layers can be deposed with hydrocarbons 209 and particles 210, which particles 210 can be ceramic or metal.

In some embodiments, the deposition chamber can be a vacuum chamber that is pumped down by a series of vacuum pumps, which control the pressure through pressure sensors and throttle valves. The base pressure in the vacuum chamber is preferred to be below 5×10⁻⁷ mbar, better to be below 1×10⁻⁷ mbar and allowed to be up to 5×10⁻⁶ mbar. Initially the chamber is pumped down from atmosphere using a dry vacuum pump and evacuation is done carefully via a soft-pump valve, so no particulates are disturbed. The typical working pressure is maintained at 1×10⁻⁴ to 3×10⁻³ mbar by turbomolecular pump with speed control or controlled with throttle valves.

The distance between the ion source the substrate is at least about 15 cm and up to 50 cm. The residence time of the species travelling through the high dense plasma is important in achieving a highly ionized flux towards the substrate. The high level of ionization allows the process to work at pressures in the E-4 mbar (10⁻⁴) range and up to the E-1 mbar (10⁻¹) range. The deposition action of the plasma ions by the substrate which is put to a negative mid frequency self-bias voltage of typically about 100V to about 300V, with a frequency from about 50 khz to about 320 khz, or a pulsed DC bias of up to 800 V negative with around 40-65% of ON cycle time.

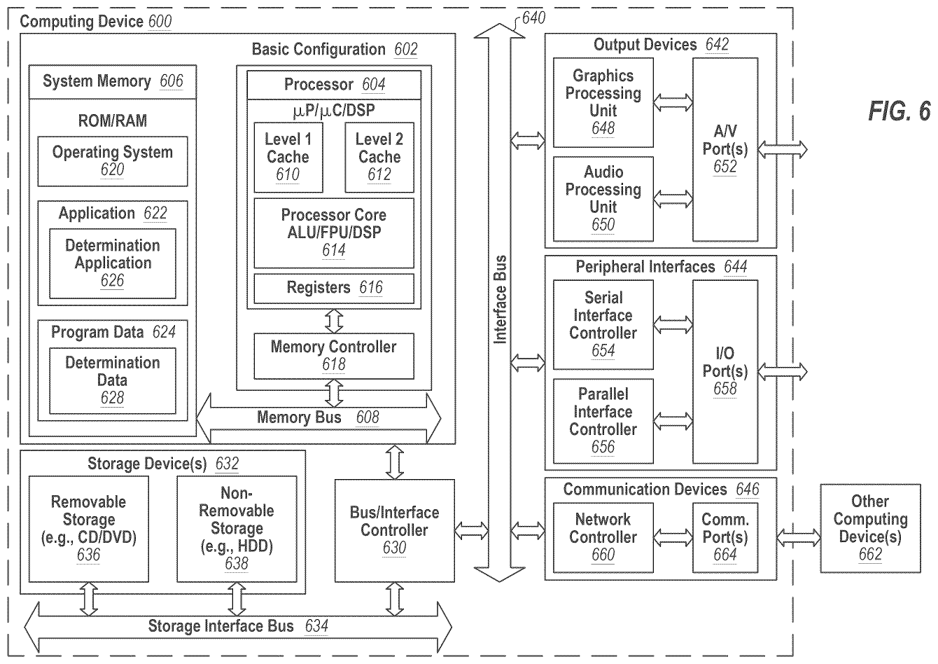

Additionally, a computing device 600, such as in FIG. 6, can be operably coupled with each of the components of the system. The computing device 600 can function as a controller for the vacuum chamber and components. As such, the computing device 600 can receive operational data from the components, and provide instructional data to the components to initiate, modulate, or terminate operation. The computing device 600 can also receive sensor data that can be processed in order to provide instructional data. The computing device can be configured to operate the system in order to perform the methods described herein. A such, a memory device (e.g., system memory 606) can include computer-executable instructions for performing the method of operating the vacuum chamber in order to manufacture the coating material as described herein.

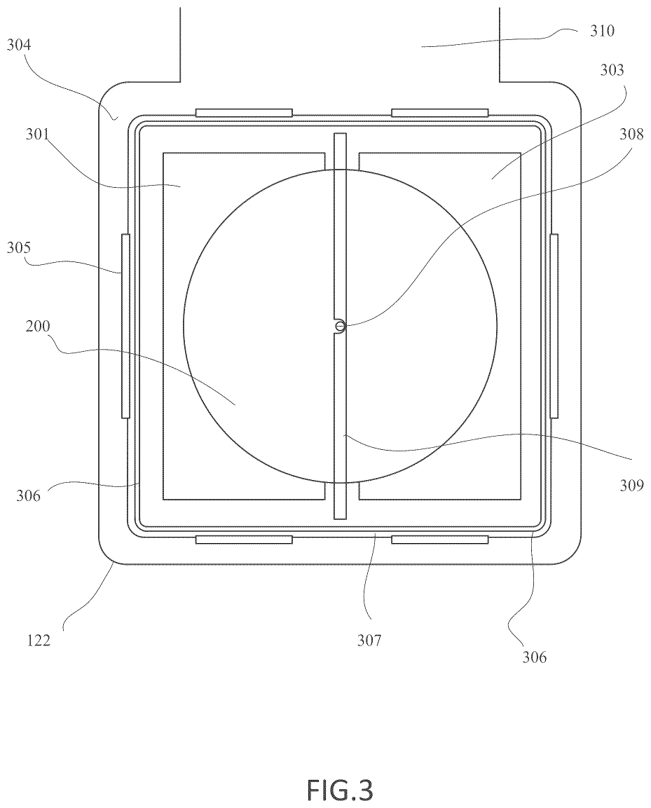

FIG. 3 shows both sides of the reactor and the coating zones of the deposition chamber 122 of FIG. 1. As such, a schematic of the deposition chamber 122 (e.g., vacuum chamber) can be seen in FIG. 3, which is split into two zones, the PVD zone 301 and the PECVD zone 303, which are separated by a divider 309, which can be a liner or shield that serves a dual purpose of preventing cross contamination between the PVD zone 301 and PECVD zone 303, and also serves as a masking shield to control deposition near the center features of the ESC. With changing the shape of the center feature 308, the system can be designed to deposit the center hole of some ESC models with either only PVD material or only PECVD material or it can be completely open or completely closed or have both sides open at the same time ranging from completely closed to 50% open. This allows to selectively deposit this center with a compound different from either the PVD zone 301 or PECVD zone 303. To promote pumping uniformity, the pump port section 304 surrounds the entire chamber and the liners 307 have a dual function and serve as deposition shield, and simultaneously perform the functions of pump uniformity shields. At several locations pump slots 305 are located to create uniformity. As the substrate or process can change, so can the divider shield 309 with different geometries. These can easily be swapped between runs and cleaned. Trim gas lines 306 aid in uniformity and can locally feed gas, which can be near the substrate 100/200 or near ICP source 113 or PVD source 108.

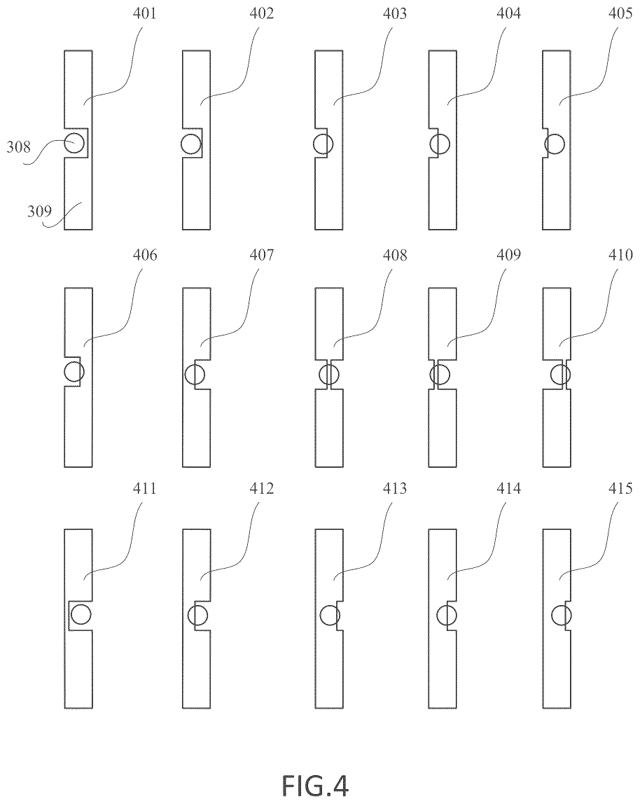

FIG. 4 illustrates a variety of liner designs obscuring either PVD or PECVD deposition or a mix of both. Accordingly, FIG. 4 illustrates the detail of the center divider 309, which can be a liner or shield which partially or fully exposes either the PVD side 301 or the PECVD side 303 to the center hole 308 in the ESC 100/200. The entire ESC will rotate, and the center area will be covered by the center divider 309. In embodiment, 401 the PVD side 301 is exposed to the center hole 308 completely. In embodiment 411, the center hole 308 is completely exposed to the PECVD side 303. The embodiments 402-410 and 412-415 are variations between these two, or are gradients where either one side is completely shielded and the other side has a gradually more open orifice or both sides are exposed (e.g., embodiment 408) half and half or slightly preferential to either or the other side. This allows for the center area to be either fully electrically conductive, fully electrical insulated or any gradient in-between. The divider 309 includes a recess or slot to accommodate the hole 308 as shown.

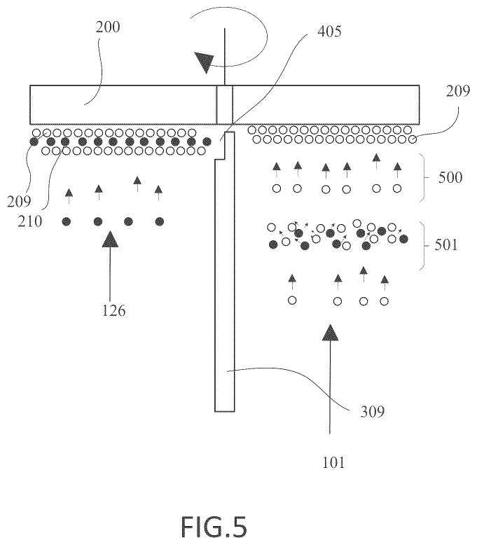

FIG. 5 shows how one revolution and a pass through both chambers constructs the blended layer. which illustrates the mechanism of the coating layer construction. As shown, the substrate 200 rotates, which exposes the substrate to either the PECVD zone 101 or PVD zone 126. One to a few atomic layers of hydrocarbons 209 are deposited and the coating rotates to the PVD zone 126 by rotating underneath and past the divider 309. This divider 309 has a recess feature 405 as seen in FIG. 4 that allows for the center hole 308 in the ESC 100/200 to be exposed to either coating zones. For illustration, the figure demonstrates a full PVD exposure here. As this atomic layer(s) of hydrocarbons enters the PVD area it gets coated with metal or ceramic particles 210. The process repeats itself and upon entering the PECVD zone 101 the impeding DLC or DLN ions have obtained enough energy so they can penetrate the previous few atomic layers and create a blended structure 500. Another blended structure 501 is shown over the first blended structure 500. This process repeats itself time over time until a desired property or film thickness has been achieved.

In some embodiments, the system is configured so that during a deposition protocol it does not co-deposit metal flux into a DLC flux. Instead, the system is configured to coat a very thin atomic layer of either the metal flux or the DLC flux in alternating steps. The system also has the ability to add dopants to either deposition flux. One side of the deposition chamber has the ability to deposit DLC material using a gas source, which is typically methane, butene, butane, acetylene, benzene or other hydrocarbons, which gas source can be from an evaporated liquid source, such as n-hexane, cyclohexane, pentane, toluene, and others.

For the creation of a DLN flux for deposition with the metal flux, the source can also use organosilicons after evaporation, such as hexamethyldisiloxane, dimethyladamantane, and others. The other side of the deposition chamber can include one or more sputter sources or PVD

sources that can be powered by a DC, pulsed DC or RF source. The deposition method can be fully metallic, reactive, or pseudo reactive, which allows the deposition of metals and non-conductive materials, such as ceramics.

During operation and rotation of the substrate which traverses both deposition chambers, the substrate can receive the respective coatings when in each chamber. The dwell time of the substrate in one part or side of the reactor is short enough to assure layers are not overly thick, and such thickness can be typically only a few atoms or even a single atomic layer. As the substrate region passes to the next chamber the energy of the second layer, which tends to be metallic, but can be a variety of ceramic as well, is sufficient to penetrate the DLC or DLN layer so it can connect with the previous metallic layer assuring electrical continuity. This technique can be used to control the conductivity of the DLC or DLN. The speed of the rotation of the substrate is of sufficient speed, such as between 40 and 1000 rotations per minute, in order to allow proper deposition. However, the rotational speed can be modulated to be higher or lower. The rotation speed determines the thickness of each deposited layer, and the recommended speeds can produce a thickness that may be or slightly above the thickness of a monolayer.

The properties of the compounds of the two different layers can exhibit material characteristics as if these two materials were co-deposited together. As a result, the deposited material does not exhibit characteristics of two different materials that are deposited on top of each other. However, slower rotations speeds would allow materials to grow thicker and the blended characteristics would disappear, and the alternating layers can have alternating properties instead of blending.

In some embodiments, the layers can be mixed by alternating deposition as described herein by increasing the velocity of the flux by adjusting the pressure or power of the ICP source, which can be adjusted so that the flux can penetrate up to a few monolayers (e.g., 2, 3, or 4 layers of penetration). Faster rotational speeds can allow for deposition to reach the substrate as the velocity from sputtered flux and DLC flux far exceeds the window or residence time or dwell time of the hole or slot in the mask on the substrate as it rotates by. The ionization level is high and plasma density can always reach values of more than 1E12/cm3 so the need of substrate bias has been eliminated or reduced.

The prior art created doped DLC or DLN that relies on a limited amount of doped hydrocarbons, such as organosilicon compounds. Although these organosilicon compounds can be synthesized to create desired compounds, the process is limited in properties dictated by hydrogen levels.

Typical DLC and DLN layers are likely to be higher stressed, where stress levels between 1 GpA and 4 GpA can be common but may be as high as 9 GpA. These DLC layers are also commonly deposited onto a metallic adhesion layer with different stress levels, where the DLC or DLN can exert enough force to pull the coating away from the substrate.

In some embodiments, the system has the ability to create very low stressed DLC layers with stress levels as low as 0.1 GpA. The ion energy, dopant type and quantity, as well as the ion flux of each emitter (e.g., each side of the deposition chamber) can be adjusted on the fly independently from one another, allowing for gradient Sp2/Sp3 compositions, gradient hydrogen content, and gradient stress levels. The system thus allows for sufficient adhesion as well as tailored hardness and composition characteristics.

In some embodiments, the system can create DLC films from a variety of precursors with hydrogen levels ranging from below 3% to higher than 55%. During any transition process, the film can either be doped with one atomic layer at a time with one or a combination of transition metals of 1b-7b, 8b groups (e.g., IB, IIB, IIIB, IVB, VB, VIB, VIIB, and VIIIB) of the periodic table, while allowing control of the Sp2/Sp3 ratio of the grown film structure. The RF-ICP source has the ability to provide almost any known gas. Also, the final DLC step could be treated with an ionized fluoride plasma to create the lotus effect and provide superhydrophobic properties and/or a very hard tetrahedral DLC with low hydrogen content with a hardness reaching 20-35 GPA.

In some embodiments, the system is advantageous in that the deposited PVD film applied via one side of the deposition chamber can receive an adhesion treatment when entering the ICP area as a monolayer and get compacted by the flux of ions and electrons emitted by the ICP source. The power level is controllable and ranges from 0 eV to 250 eV, which can be dependent on the type of source selected. The higher energy levels are not recommended as a packing force but could be helpful to remove impurities from the film or create a virgin substrate, such as when entering etching territories.

In some embodiments, the coatings formed herein can be used to create a hydrophobic or oleophobic effect onto displays or screens, which can be glass or other material. In the case of displays and screens used, but not limited to the consumer market, the coating can be between 5 nanometer and 1 micron in mechanical thickness as it must be transparent in the VIS range between 350 and 1200 nanometer. Films in that range are >80% in transmittance.

In some embodiments, any of the layers, such as a top layer, can be treated with a fluorine post processing, which creates a surface modification like the lotus effect (e.g., the lotus effect refers to self-cleaning properties that are a result of ultrahydrophobicity as exhibited by the leaves of Nelumbo or “lotus flower”. Dirt particles are picked up by water droplets due to the micro- and nanoscopic architecture on the surface, which minimizes the droplet's adhesion to that surface) seen on some tree leaves. However, the fluorine may be introduced during the deposition, such as by one of the manifolds.

In some aspects, the processing with the system uses a fluorine-containing material, which can be any fluoride source substance, typically but not limited to CF₄ (carbon tetrafluoride). Other molecules with fluorine that can generate ionic fluoride may be sources.

Because of their chemical inertness, low wear and intrinsic smoothness, these films give access to appealing industrial applications such as hard, self-lubricating films where temperature resistance and cleanliness are important, e.g., for protection of acronautic applications and space applications, harsh media pumps and consumer products. In addition, because of its ionic barrier properties, low internal stress and bio compatibility, it is a perfect candidate for intravascular devices and other implants.

Also, drivetrain components operating in sustained continuous high temperature exposure including but not limited to cylinder heads and turbochargers. The high temperature resistance in high oxygen environments combined with the dry lubricating properties of this coating will appeal to the aeronautics and space industry where durable wear resistant coatings are desired and where lubrication cannot be applied. Applications targeted include but are not limited to turbine blades and bearings. Besides serving as a protective film for semiconductor pedestals where the electrostatic chucking processes relies on Johnsen-Rahbek or Coulomb, these films can also be applied in process chambers and vacuum load-locks for covering substrates with a layer or film of such a composition where it withstands high temperature PVD, CVD and etch processes.

One skilled in the art will appreciate that, for the processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

In one embodiment, the present methods can include aspects performed on a computing system. As such, the computing system can include a memory device that has the computer-executable instructions for performing the methods. The computer-executable instructions can be part of a computer program product that includes one or more algorithms for performing any of the methods of any of the claims.

In one embodiment, any of the operations, processes, or methods, described herein can be performed or cause to be performed in response to execution of computer-readable instructions stored on a computer-readable medium and executable by one or more processors. The computer-readable instructions can be executed by a processor of a wide range of computing systems from desktop computing systems, portable computing systems, tablet computing systems, hand-held computing systems, as well as network elements, and/or any other computing device. The computer readable medium is not transitory. The computer readable medium is a physical medium having the computer-readable instructions stored therein so as to be physically readable from the physical medium by the computer/processor.

There are various vehicles by which processes and/or systems and/or other technologies described herein can be effected (e.g., hardware, software, and/or firmware), and that the preferred vehicle may vary with the context in which the processes and/or systems and/or other technologies are deployed. For example, if an implementer determines that speed and accuracy are paramount, the implementer may opt for a mainly hardware and/or firmware vehicle; if flexibility is paramount, the implementer may opt for a mainly software implementation; or, yet again alternatively, the implementer may opt for some combination of hardware, software, and/or firmware.

The various operations described herein can be implemented, individually and/or collectively, by a wide range of hardware, software, firmware, or virtually any combination thereof. In one embodiment, several portions of the subject matter described herein may be implemented via application specific integrated circuits (ASICs), field programmable gate arrays (FPGAs), digital signal processors (DSPs), or other integrated formats. However, some aspects of the embodiments disclosed herein, in whole or in part, can be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware are possible in light of this disclosure. In addition, the mechanisms of the subject matter described herein are capable of being distributed as a program product in a variety of forms, and that an illustrative embodiment of the subject matter described herein applies regardless of the particular type of signal bearing medium used to actually carry out the distribution. Examples of a physical signal bearing medium include, but are not limited to, the following: a recordable type medium such as a floppy disk, a hard disk drive (HDD), a compact disc (CD), a digital versatile disc (DVD), a digital tape, a computer memory, or any other physical medium that is not transitory or a transmission. Examples of physical media having computer-readable instructions omit transitory or transmission type media such as a digital and/or an analog communication medium (e.g., a fiber optic cable, a waveguide, a wired communication link, a wireless communication link, etc.).

It is common to describe devices and/or processes in the fashion set forth herein, and thereafter use engineering practices to integrate such described devices and/or processes into data processing systems. That is, at least a portion of the devices and/or processes described herein can be integrated into a data processing system via a reasonable amount of experimentation. A typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems, including feedback loops and control motors (e.g., feedback for sensing position and/or velocity; control motors for moving and/or adjusting components and/or quantities). A typical data processing system may be implemented utilizing any suitable commercially available components, such as those generally found in data computing/communication and/or network computing/communication systems.

The herein described subject matter sometimes illustrates different components contained within, or connected with, different other components. Such depicted architectures are merely exemplary, and that in fact, many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to: physically mateable and/or physically interacting components and/or wirelessly interactable and/or wirelessly interacting components and/or logically interacting and/or logically interactable components.

FIG. 6 shows an example computing device 600 (e.g., a computer) that may be arranged in some embodiments to perform the methods (or portions thereof) described herein. In a very basic configuration 602, computing device 600 generally includes one or more processors 604 and a system memory 606. A memory bus 608 may be used for communicating between processor 604 and system memory 606.

Depending on the desired configuration, processor 604 may be of any type including, but not limited to: a microprocessor (μP), a microcontroller (μC), a digital signal processor (DSP), or any combination thereof. Processor 604 may include one or more levels of caching, such as a level one cache 610 and a level two cache 612, a processor core 614, and registers 616. An example processor core 614 may include an arithmetic logic unit (ALU), a floating-point unit (FPU), a digital signal processing core (DSP Core), or any combination thereof. An example memory controller 618 may also be used with processor 604, or in some implementations, memory controller 618 may be an internal part of processor 604.

Depending on the desired configuration, system memory 606 may be of any type including, but not limited to: volatile memory (such as RAM), non-volatile memory (such as ROM, flash memory, etc.), or any combination thereof. System memory 606 may include an operating system 620, one or more applications 622, and program data 624. Application 622 may include a determination application 626 that is arranged to perform the operations as described herein, including those described with respect to methods described herein. The determination application 626 can obtain data, such as pressure, flow rate, and/or temperature, and then determine a change to the system to change the pressure, flow rate, and/or temperature.

Computing device 600 may have additional features or functionality, and additional interfaces to facilitate communications between basic configuration 602 and any required devices and interfaces. For example, a bus/interface controller 630 may be used to facilitate communications between basic configuration 602 and one or more data storage devices 632 via a storage interface bus 634. Data storage devices 632 may be removable storage devices 636, non-removable storage devices 638, or a combination thereof. Examples of removable storage and non-removable storage devices include: magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include: volatile and non-volatile, removable and non-removable media implemented in any method or technology for storage of information, such as computer readable instructions, data structures, program modules, or other data.

System memory 606, removable storage devices 636 and non-removable storage devices 638 are examples of computer storage media. Computer storage media includes, but is not limited to: RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which may be used to store the desired information, and which may be accessed by computing device 600. Any such computer storage media may be part of computing device 600.

Computing device 600 may also include an interface bus 640 for facilitating communication from various interface devices (e.g., output devices 642, peripheral interfaces 644, and communication devices 646) to basic configuration 602 via bus/interface controller 630. Example output devices 642 include a graphics processing unit 648 and an audio processing unit 650, which may be configured to communicate to various external devices such as a display or speakers via one or more A/V ports 652. Example peripheral interfaces 644 include a serial interface controller 654 or a parallel interface controller 656, which may be configured to communicate with external devices such as input devices (e.g., keyboard, mouse, pen, voice input device, touch input device, etc.) or other peripheral devices (e.g., printer, scanner, etc.) via one or more I/O ports 658. An example communication device 646 includes a network controller 660, which may be arranged to facilitate communications with one or more other computing devices 662 over a network communication link via one or more communication ports 664.

The network communication link may be one example of a communication media. Communication media may generally be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), microwave, infrared (IR), and other wireless media. The term computer readable media as used herein may include both storage media and communication media.

Computing device 600 may be implemented as a portion of a small-form factor portable (or mobile) electronic device such as a cell phone, a personal data assistant (PDA), a personal media player device, a wireless web-watch device, a personal headset device, an application specific device, or a hybrid device that includes any of the above functions. Computing device 600 may also be implemented as a personal computer including both laptop computer and non-laptop computer configurations. The computing device 600 can also be any type of network computing device. The computing device 600 can also be an automated system as described herein.

The embodiments described herein may include the use of a special purpose or general-purpose computer including various computer hardware or software modules.

Embodiments within the scope of the present invention also include computer-readable media for carrying or having computer-executable instructions or data structures stored thereon. Such computer-readable media can be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium which can be used to carry or store desired program code means in the form of computer-executable instructions or data structures and which can be accessed by a general purpose or special purpose computer. When information is transferred or provided over a network or another communications connection (either hardwired, wireless, or a combination of hardwired or wireless) to a computer, the computer properly views the connection as a computer-readable medium. Thus, any such connection is properly termed a computer-readable medium. Combinations of the above should also be included within the scope of computer-readable media.

Computer-executable instructions comprise, for example, instructions and data which cause a general purpose computer, special purpose computer, or special purpose processing device to perform a certain function or group of functions. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

In some embodiments, a computer program product can include a non-transient, tangible memory device having computer-executable instructions that when executed by a processor, cause performance of a method that can include: providing a dataset having object data for an object and condition data for a condition; processing the object data of the dataset to obtain latent object data and latent object-condition data with an object encoder; processing the condition data of the dataset to obtain latent condition data and latent condition-object data with a condition encoder; processing the latent object data and the latent object-condition data to obtain generated object data with an object decoder; processing the latent condition data and latent condition-object data to obtain generated condition data with a condition decoder; comparing the latent object-condition data to the latent-condition data to determine a difference; processing the latent object data and latent condition data and one of the latent object-condition data or latent condition-object data with a discriminator to obtain a discriminator value; selecting a selected object from the generated object data based on the generated object data, generated condition data, and the difference between the latent object-condition data and latent condition-object data; and providing the selected object in a report with a recommendation for validation of a physical form of the object. The non-transient, tangible memory device may also have other executable instructions for any of the methods or method steps described herein. Also, the instructions may be instructions to perform a non-computing task, such as synthesis of a molecule and or an experimental protocol for validating the molecule. Other executable instructions may also be provided.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

All references recited herein are incorporated herein by specific reference in their entirety. This application incorporates U.S. Pat. No. 11,639,543 herein in its entirety.

1. A deposition system for forming coatings, comprising:
a deposition chamber;
a substrate in the deposition chamber configured for receiving a vapor deposition;
a motor operably coupled with the substrate to rotate the substrate;
a first deposition source separated from the substrate;
a second deposition source separated from the substrate, wherein the second deposition source is configured to generate a second deposition material that is different from a first deposition material generated by the first deposition source;
a divider in the deposition chamber between the first deposition source and the second deposition source,
wherein at least one of the first deposition source or second deposition source includes an inductively coupled plasma generator.

2. The deposition system of claim 1, wherein:
the first deposition source is configured for physical vapor deposition (PVD); and
the second deposition source is configured for plasma-enhanced chemical vapor deposition (PECVD).

3. The deposition system of claim 2, wherein:
the PVD is operably coupled with a metal supply or ceramic supply; and
the PECVD is operably coupled with a plurality of material supplies for forming diamond-like coatings (DLC) or diamond-like nanocomposites (DLN).

4. The deposition system of claim 1, wherein the first deposition source and second deposition source are each positioned to create a deposition that is substantially normal to the substrate.

5. The deposition system of claim 1, wherein the divider extends longitudinally at least 25% of a trajectory length from the first and second deposition sources to the substrate.

6. The deposition system of claim 1, wherein the divider extends laterally between the first and second deposition sources by at least 25% of a lateral length of the deposition chamber.

7. The deposition system of claim 1, wherein the inductively coupled plasma generator is remote from the deposition chamber.

8. The deposition system of claim 1, wherein the substrate is un-biased during operation for deposition of materials.

9. The deposition system of claim 1, further comprising a remote power supply configured as a radio frequency inductively coupled plasma generator.

10. The deposition system of claim 3, wherein:
the metal supply includes materials selected from titanium, aluminum, chromium, gold, nickel, silver, copper, zirconium, tantalum, molybdenum, alloys thereof, or combinations thereof;
the ceramic supply includes materials selected from silicon nitride, silicon dioxide, aluminum oxide, titanium dioxide, zirconium dioxide, tantalum pentoxide, hafnium dioxide, silicon carbide, boron nitride, gallium nitride, constituent atoms thereof, or combinations thereof;
the plurality of material supplies for forming the DLC or DLN includes materials selected from silicone, organosilicone, hexamethyldisiloxane, dimethyladamantane, oxygen, nitrogen, carbon, silicon, hydrocarbon, fluorine, hydrogen, fluorinated hydrocarbon, DLC dopant, DLN dopant, or combinations thereof.

11. The deposition system of claim 1, further comprising at least a first emitter manifold associated with the first deposition source within a first region relative to the divider, and at least a second emitter manifold associated with the second deposition source within a second region relative to the divider.

12. The deposition system of claim 11, further comprising a plurality of first emitter manifolds in the first region and a plurality of second emitter manifolds in the second region.

13. The deposition system of claim 1, wherein the divider has a shape that at least partially block or at least partially expose a center hole in the substrate.

14. A method of forming a deposited material, comprising:
providing the deposition system of claim 1;
rotating the substrate;
generating a first deposition material from the first deposition source with a trajectory towards the rotating substrate;
generating a second deposition material from the second deposition source with a trajectory towards the rotating substrate; and
forming a hybrid material from the first deposition material and second deposition material, wherein the hybrid material includes alternating layers or blending.

15. The method of claim 14, further comprising at least one of:
operating a power supply for the inductively coupled plasma generator with an energy range of 10 eV to 250 eV;
depositing the hybrid material a rate of about 2.5 nm per second to about 9 μm per hour;
rotating the substrate at about 200 to about 250 rotations per minutes via the motor; or
creating a vacuum in the deposition chamber from about 1×10-7 mbar to about 5×10-6 mbar.

16. The method of claim 14, further comprising forming a Sp2 rich film and transitioning to forming a Sp3 rich film; or
forming a Sp3 rich film and transitioning to forming a Sp2 rich film,
wherein said transitioning includes modulating hydrogen content in the deposition chamber.

17. The method of claim 14, wherein the first deposition source is configured for physical vapor deposition (PVD) and the second deposition source is configured for plasma-enhanced chemical vapor deposition (PECVD), wherein the PVD is operably coupled with a metal supply and the PECVD is operably coupled with a plurality of material supplies for forming diamond-like coatings (DLC) or diamond-like nanocomposites (DLN).

18. The method of claim 14, wherein the first deposition source and second deposition source are each positioned to create a deposition that is substantially normal to the substrate, the method comprising creating a flux of the first deposition material toward the substrate in a first region of the deposition chamber and creating a flux of the second deposition material toward the substrate in a second region of the deposition chamber.

19. The method of claim 14, comprising generating a inductively coupled plasma with an RF plasma generator.

20. The method of claim 19, wherein the RF plasma generator is remote from the deposition chamber.
